(19) United States
(12) Patent Application Publication
(10) Pub. No.: US 2025/0158190 A1
(43) Pub. Date: May 15, 2025

(54) FLEXIBLE PRINTED CIRCUIT BOARD AND SECONDARY BATTERY MODULE INCLUDING THE SAME

(71) Applicant: LG ENERGY SOLUTION, LTD., Seoul (KR)

(72) Inventors: Won Tae LEE, Daejeon (KR); Chang Bok LEE, Daejeon (KR); Kyu Hwan OH, Daejeon (KR); Sung Tack HWANG, Daejeon (KR)

(21) Appl. No.: 18/840,047

(22) PCT Filed: Feb. 24, 2023
(86) PCT No.: PCT/KR2023/002679

§ 371 Date: Aug. 20, 2024

(30) Foreign Application Priority Data
Feb. 24, 2022 (KR) 10-2022-0024705

(51) Int. Cl. H01M 50/211; H01M 10/48; H01M 50/284; H01M 50/507; H01M 50/519; H01M 50/569

(52) U.S. Cl. CPC H01M 50/211; H01M 10/482; H01M 50/284; H01M 50/507; H01M 50/519; H01M 50/569

(57) ABSTRACT

The present disclosure has been devised to solve the problems as above and an object of the present disclosure is to provide a flexible printed circuit board, which is capable of detecting and continuously monitoring it through a simple structure change whether a secondary battery module is submerged or an electrolyte of a pouch cell leaks in the secondary battery module, so that quality and safety of the battery is secured and also space utilization and energy density in the module is maximized, and a secondary battery module including the flexible printed circuit.

A secondary battery module according to Embodiment 1 of the present disclosure includes a pouch cell assembly, in which a plurality of pouch cells are arranged in a thickness direction, a busbar frame assembly, which is coupled to each of one side and the other side of the pouch cell assembly, and a flexible printed circuit board which is coupled to the busbar frame assembly and in which a film layer is stacked on at least one surface of a metal layer. The flexible printed circuit board includes a body part, which is provided between the busbar frame assemblies coupled to the one side and the other side of the pouch cell assembly, respectively, and a sensing part which extends from the body part, wherein the sensing part extends from at least one of one side or the other side in a longitudinal direction of the body part, and is provided at each of one side and the other side in a width direction of the body part to sense leakage of moisture or an electrolyte.

### CROSS-REFERENCE TO RELATED APPLICATION

The present application is a National Phase entry pursuant to 35 U.S.C. § 371 of International Application No. PCT/KR2023/002679, filed on Feb. 24, 2023, and claims the benefit of and priority to Korean Patent Application No. 10-2022-0024705, filed on Feb. 24, 2022, the entire contents of which are hereby incorporated by reference in their entirety.

### TECHNICAL FIELD

The present disclosure relates to a flexible printed circuit board and a secondary battery module including the same, and more particularly, to a flexible printed circuit board, which is capable of detecting and continuously monitoring whether a secondary battery module is submerged or an electrolyte of a pouch cell leaks in the secondary battery module, and a secondary battery module including the flexible printed circuit.

### BACKGROUND

Secondary batteries refer to batteries that are chargeable and dischargeable unlike non-rechargeable primary batteries, and types of the secondary batteries include a nickel-cadmium battery, a nickel-hydrogen battery, a lithium-ion battery, a lithium-ion polymer battery, and the like. These secondary batteries are applied to and used in not only products such as digital camera, notebook computer, small mobile phone, PDA and E-bike, but also large products, such as electric vehicle and hybrid vehicle, which require higher powers, energy storage systems for storing surplus electricity or new renewable energy, and energy storage systems for backup.

These secondary batteries are classified into a pouch type, a can type, and the like, according to a material of a battery case that accommodates an electrode assembly. In the pouch type, the electrode assembly is accommodated in a pouch made of a flexible polymer material having a variable shape.

In the can type, the electrode assembly is accommodated in a case made of a material such as metal or plastic, which has a fixed shape.

The secondary batteries may be configured as a cell, a module, or a pack according to a gathering unit of the secondary batteries. First, the cell is a radical unit of a secondary battery, which is capable of being used by charging and discharging electrical energy, and may be the pouch type secondary battery, the can type secondary battery, or the like, which are described above.

FIG. 1 is a perspective view illustrating a secondary battery module according to the related art. FIG. 2 is a perspective view illustrating main components of a secondary battery module according to the related art. Referring to FIGS. 1 and 2, a module 1 means a unit assembly in which cells are bundled in a fixed number, or a predetermined number of cell assemblies 2 are provided and then, accommodated in a frame to protect the cells from an external impact, heat, vibration, or the like, as illustrated in FIG. 1. In particular, the module may include, in addition to the cell assemblies 2, a fixing plate 3 (or busbar frame assembly) on which a busbar that electrically connects the cell assemblies is seated and which fixes a pouch cell assembly, a circuit board 4 which measures a cell voltage, temperature, or the like in the module to transmit the same to the outside, and so on.

In addition, the pack is a final form of a battery system and completed by mounting various control and protection systems such as BMS and cooling system, on the secondary battery module.

In a pouch type cell, an electrolyte injected into the cell may leak in the module due to a sealing defect of the pouch, damage to the pouch, or the like. In this case, corrosion of the pouch may occur, and the corrosion may lead to performance degradation of the battery or fire of a vehicle so that quality reliability of products is reduced and user's safety is seriously threatened.

Thus, there is a need to check it during a manufacturing process whether the electrolyte of the cell leaks in the completely assembled module, and there is a need to continuously monitor the module or pack also in a field after the module or pack is assembled with the vehicle, to secure the safety.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

### Technical Problem

The present disclosure has been devised to solve the problems as above and an object of the present disclosure is to provide a flexible printed circuit board, which is capable of detecting and continuously monitoring it through a simple structure change whether a secondary battery module is submerged or an electrolyte of a pouch cell leaks in the secondary battery module, so that quality and safety of the battery is secured and also space utilization and energy density in the module is maximized, and a secondary battery module including the flexible printed circuit.

### Technical Solution

A secondary battery module according to Embodiment 1 of the present disclosure includes a pouch cell assembly, comprising a plurality of pouch cells arranged in a thickness direction, a pair of busbar frame assemblies coupled to each of a first side and a second side of the pouch cell assembly, and a flexible printed circuit board (FPCB) coupled to each of the busbar frame assemblies and having a metal layer and a film layer on at least one surface of the metal layer. The flexible printed circuit board includes a body part provided between the pair of busbar frame assemblies coupled to the first side and the second side of the pouch cell assembly, respectively, and a sensing part extending from the body part, wherein the sensing part extends from one side or both sides in a longitudinal direction of the body part which is parallel to the thickness direction of the pouch cell assembly, and provided at both sides in a width direction of the body part to sense leakage of moisture or an electrolyte.

The sensing part may include a first extension line part, which extends toward one side in the width direction of the body part, and a second extension line part which extends toward the other side in the width direction of the body part.

Each of the first extension line part and the second extension line part may be bent along a circumference of each of the busbar frame assemblies.

Each of the first extension line part and the second extension line part may have an end, respectively, and the ends of the first extension line part and the second extension line part are bent to face each other in a state of being spaced apart by a predetermined gap from each other.

The first extension line part may have a first end having a first exposed portion at which the metal layer is exposed, and the second extension line part may have a second end having a second exposed portion at which the metal layer is exposed.

The sensing part may sense whether the first exposed portion and the second exposed portion are electrically connected to each other by moisture or electrolyte.

Each of the busbar frame assemblies may include: a busbar, which is electrically coupled to an electrode lead of the pouch cell assembly; and a fixing plate comprising a lead insertion part having a slit allowing the electrode lead to pass through front and rear surfaces of the fixing plate so that the electrode lead is inserted thereinto, a busbar seating part provided at one side of the lead insertion part, and a terrace part extending from a lower portion of the lead insertion part to a side of the pouch cell assembly. The first exposed portion and the second exposed portion may be disposed on a top surface of the terrace part.

Each of the busbar frame assemblies may further include a cover plate covering the busbar and is coupled to the fixing plate.

The secondary battery module may further include: a housing, which has both ends opened and in which the pouch cell assembly and the pair of busbar frame assemblies are accommodated, and an end plate covering each of the opened ends of the housing.

The secondary battery module may further include a connector transmitting a signal output from the flexible printed circuit board to an external battery management system (BMS).

A terrace part of a secondary battery module according to the present disclosure may include a first inclined part having a height that gradually decreases from one side of the terrace part to a center, and a second inclined part having a height that gradually decreases from the other side of the terrace part to the center, wherein the first exposed portion is disposed on a top surface of the first inclined part, and the second exposed portion is disposed on a top surface of the second inclined part.

A flexible printed circuit board according to Embodiment 2 of the present disclosure is a flexible printed circuit board (FPCB) in which a film layer is stacked on at least one surface of a metal layer. The flexible printed circuit board includes: a body part; and a sensing part extending from the body part and provided at both sides in a width direction of the body part to sense leakage of moisture or an electrolyte, wherein the sensing part extends from one side or both sides in a longitudinal direction of the body part.

The sensing part may further include a first extension line part, which extends toward one side in the width direction of the body part, and a second extension line part, which extends toward the other side in the width direction of the body part.

The first extension line part may extend toward the one side in the width direction of the body part and have an area of at least a portion including a firest end, which is provided to be parallel to the longitudinal direction of the body part. The second extension line part may extend toward the other side in the width direction of body part and have an area of at least a portion including a second end, which is provided to be parallel to the longitudinal direction of the body part.

Each of the first extension line part and the second extension line part may be bendable.

The first extension line part may have the first end having a first exposed portion at which the metal layer is exposed, and the second extension line part may have the second end having a second exposed portion at which the metal layer is exposed.

The sensing part may sense whether the first exposed portion and the second exposed portion are electrically connected to each other by moisture or electrolyte.

### Advantageous Effects

The secondary battery module according to the present disclosure includes the pouch cell assembly, in which the plurality of pouch cells are arranged in the thickness direction, the busbar frame assembly, which is coupled to each of the one side and the other side of the pouch cell assembly, and the flexible printed circuit board (FPCB) which is coupled to the busbar frame assembly and in which the film layer is stacked on the at least one surface of the metal layer. The flexible printed circuit board includes the body part, which is provided between the busbar frame assemblies coupled to the one side and the other side of the pouch cell assembly, respectively, and the sensing part, which extends from the body part, extending from the at least one of the one side or the other side in the longitudinal direction of the body part and provided at each of the one side and the other side in the width direction of the body part to sense the moisture or the leakage of the electrolyte. Through this simple structure change, it may be detected and continuously monitored whether the secondary battery module is submerged or the electrolyte of the pouch cell leaks in the secondary battery module, and the quality and safety of the battery may be secured and also the space utilization and energy density in the module may be maximized.

### BRIEF DESCRIPTION OF THE DRAWINGS

FIG. 1 is a perspective view illustrating a secondary battery module according to the related art.

FIG. 2 is a perspective view illustrating main components of a secondary battery module according to the related art.

FIG. 3 is an exploded perspective view illustrating a secondary battery module according to Embodiment 1 of the present disclosure.

FIG. 4 is a perspective view illustrating main components of the secondary battery module according to Embodiment 1 of the present disclosure.

FIG. 5 is a perspective view illustrating a flexible printed circuit board, a fixing plate, and a connector of the secondary battery module according to Embodiment 1 of the present disclosure.

FIG. 6a is a side view illustrating an area A in FIG. 5 when viewed from a side. FIG. 6b is a plan view illustrating the area A in FIG. 5 when viewed from above.

FIG. 7 is a perspective view illustrating a fixing plate of a secondary battery module according to Embodiment 2 of the present disclosure.

FIG. 8a is a side view illustrating a first extension line part, a second extension line part, and a terrace part of the secondary battery module according to Embodiment 2 of the present disclosure when viewed from a side. FIG. 8b is a plan view illustrating the first extension line part, the second extension line part, and the terrace part of the secondary battery module according to Embodiment 2 of the present disclosure when viewed from above.

FIG. 9a is a perspective view illustrating a flexible printed circuit board according to Embodiment 3 of the present disclosure. FIG. 9b is a perspective view illustrating a state in which a first extension line part and a second extension line part are bent in the flexible printed circuit board according to Embodiment 3 of the present disclosure.

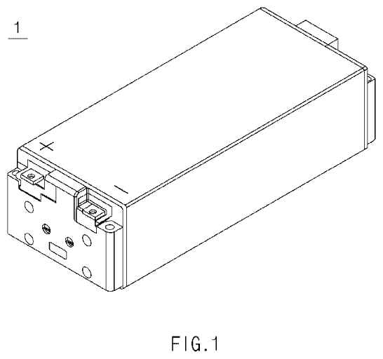

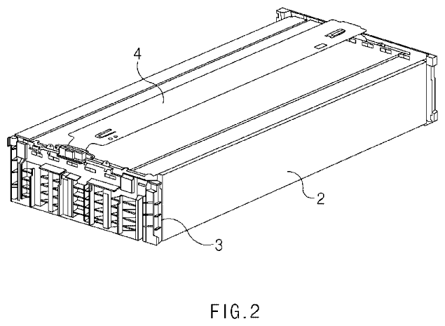

### DETAILED DESCRIPTION

Hereinafter, preferred embodiments of the present disclosure will be described in detail with reference to the accompanying drawings to enable those skilled in the art to which the present disclosure pertains to easily carry out the present disclosure. The present disclosure may, however, be embodied in different forms and should not be construed as limited by the embodiments set forth herein.

The parts unrelated to the description, or the detailed descriptions of related well-known art that may unnecessarily obscure subject matters of the present disclosure, will be ruled out in order to clearly describe the present disclosure. Like reference numerals refer to like elements throughout the whole specification.

Moreover, terms or words used in this specification and claims should not be restrictively interpreted as ordinary meanings or dictionary-based meanings, but should be interpreted as meanings and concepts conforming to the scope of the present disclosure on the basis of the principle that an inventor can properly define the concept of a term to describe and explain his or her invention in the best ways.

### Embodiment 1

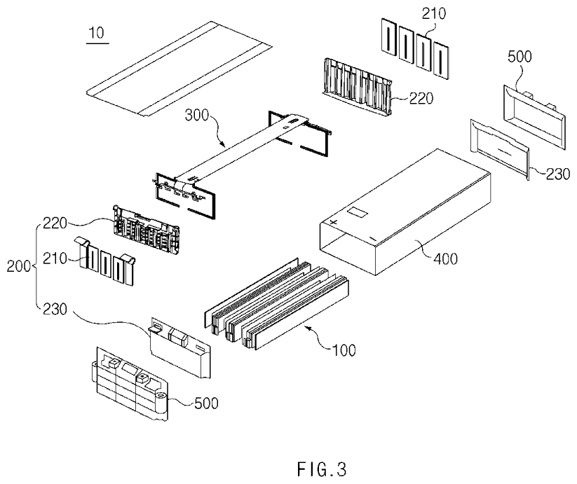

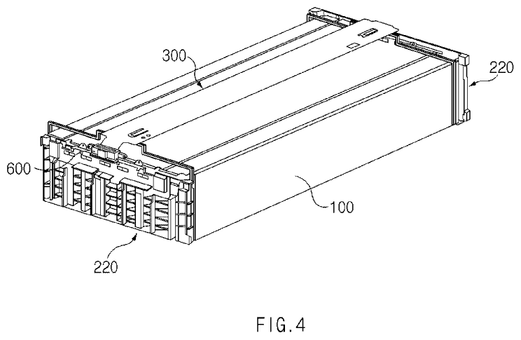

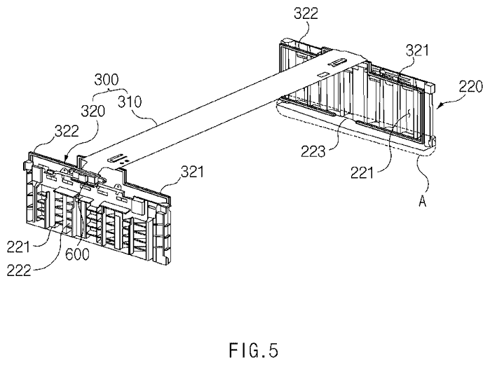

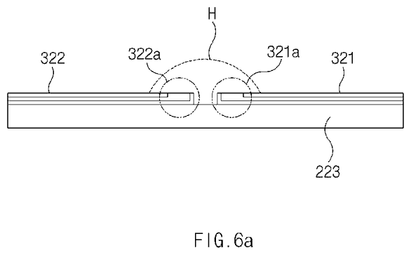

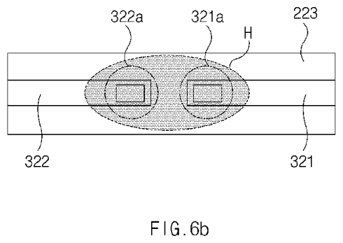

FIG. 3 is an exploded perspective view illustrating a secondary battery module according to Embodiment 1 of the present disclosure. FIG. 4 is a perspective view illustrating main components of the secondary battery module according to Embodiment 1 of the present disclosure. FIG. 5 is a perspective view illustrating a flexible printed circuit board, a fixing plate, and a connector of the secondary battery module according to Embodiment 1 of the present disclosure. FIG. 6a is a side view illustrating an area A in FIG. 5 when viewed from a side. FIG. 6b is a plan view illustrating the area A in FIG. 5 when viewed from above.

Referring to FIGS. 3 and 4, a secondary battery module 10 according to Embodiment 1 of the present disclosure includes a pouch cell assembly 100, a busbar frame assembly (BFA) 200, and a flexible printed circuit board (FPCB) 300. The pouch cell assembly 100 is provided so that a plurality of pouch cells are arranged in a thickness direction, the busbar frame assembly 200 is coupled to each of one side and the other side of the pouch cell assembly 100, the flexible printed circuit board 300 is coupled to the busbar frame assembly 200, and a film layer is stacked on at least one surface a metal layer.

In addition, the flexible printed circuit board 300 of the secondary battery module 10 according to the present disclosure includes a body part 310, which is provided between the busbar frame assemblies 200 coupled to the one side and the other side of the pouch cell assembly 100, respectively, and a sensing part 320, which extends from the body part 310, extending from at least one of one side or the other side in a longitudinal direction of the body part 310 and provided at each of one side and the other side in a width direction of the body part 310 to sense leakage of moisture or an electrolyte.

As above, the secondary battery module 10 according to the present disclosure may detect and continuously monitor whether the secondary battery module 10 is submerged or an electrolyte of a pouch cell leaks in the secondary battery module 10, through the sensing part 320 extending from the body part 310 and having a simple structure, so that quality and safety of the battery is secured. In particular, the leakage of the electrolyte be sensed by allowing the sensing part 320 to extend from the flexible printed circuit board 300, not by attaching a separate sensor to the inside of the module, so that space utilization in the module is increased and energy density of the module is maximized.

Hereinafter, each of components of the secondary battery module 10 will be described in detail.

First, referring to FIGS. 4 and 5, the sensing part 320 may include a first extension line part 321, which extends toward one side in the width direction of the body part 310, and a second extension line part 322 which extends toward the other side in the width direction of the body part 310. That is, the sensing part 320 may have two extension line parts for sensing.

Each of the first extension line part 321 and the second extension line part 322 may extend integrally from the body part 310 of the flexible printed circuit board 300. For example, the body part 310 and each of the first extension line part 321 and the second extension line part 322 may be provided by cutting the sheet-shaped flexible printed circuit board 300. Thus, in each of the first extension line part 321 and the second extension line part 322, the film layer is stacked on the at least one surface of the metal layer so as to correspond to the structure of the flexible printed circuit board 300.

Referring to FIGS. 3 and 5, each of the first extension line part 321 and the second extension line part 322 may be provided to be bendable. In particular, in the secondary battery module according to the present disclosure, each of the first extension line part 321 and the second extension line part 322 may be bent along a circumference of the busbar frame assembly 200. In more detail, each of the first extension line part 321 and the second extension line part 322 may be bent along an inner circumference of a fixing plate 220 of the busbar frame assembly 200. The bending shape of each of these first extension line part 321 and second extension line part 322 will be described in detail below together with the busbar frame assembly 200. As each of the first extension line part 321 and the second extension line part 322 is bent along the busbar frame assembly 200 as above, the space occupied in the module may be minimized to maximize the energy density, and the first extension line part 321 and the second extension line part 322 may be bent at an end of the pouch cell, which is an area in which leakage of the electrolyte well occurs, and on the circumference of the busbar frame assembly 200, which is in contact with the end of the pouch cell, to increase sensing sensitivity.

In the secondary battery module 10 according to Embodiment 1 of the present disclosure, as illustrated in FIG. 5, the first extension line part 321 and the second extension line part 322 may have ends, respectively, which are bent to face each other in a state of being spaced a predetermined gap from each other. In detail, as illustrated in FIGS. 6a and 6b, when the secondary battery module 10 is submerged or the leakage of the electrolyte occurs in the secondary battery module 10, the respective ends of the first extension line part 321 and the second extension line part 322 may be submerged together in the electrolyte or moisture H (hereinafter referred to as an electrolyte) by the electrolyte H. Here, the first extension line part 321 and the second extension line part 322 may be electrically connected to each other by the electrolyte H, and the sensing part 320 may detect the electrical connection to sense whether the leakage of the electrolyte occurs.

Thus, the predetermined gap may vary depending on the sensitivity for sensing whether the electrolyte leaks. For example, as the respective ends of the first extension line part 321 and the second extension line part 322 are closer to each other, the end of the first extension line part 321 and the end of the second extension line part 322 may be submerged together even with a small amount of the electrolyte H to be electrically connected to each other. As the respective ends of the first extension line part 321 and the second extension line part 322 are farther from each other, a large amount of the electrolyte H is required to electrically connect the ends to each other. Thus, the predetermined gap may be a gap that a designer or manufacturer designs by setting the sensitivity for sensing whether leakage of the electrolyte occurs in comprehensive consideration of the size of the module, corrosion of the battery, the amount of electrolyte leakage that may cause an occurrence of fire, or the like.

When the structure of each of the first extension line part 321 and the second extension line part 322 will continue to be described in more detail with reference to FIGS. 6a and 6b, the first extension line part 321 may have an end having a first exposed portion 321a at which a metal layer is exposed, and the second extension line part 322 may have an end having a second exposed portion 322a at which a metal layer is exposed. As described above, each of the first extension line part 321 and the second extension line part 322 extends from the flexible printed circuit board and may have a structure in which the film layer is stacked on at least one surface of the metal layer. However, each of the first exposed portion 321a and the second exposed portion 322a may be provided so that the metal layer is not blocked by the film layer and is exposed.

When the first exposed portion 321a and the second exposed portion 322a are submerged together in the electrolyte H, the first extension line part 321 and the second extension line part 322 are electrically connected to each other. As above, the sensing part 320 according to the present disclosure may sense the electrolyte H to determine whether the first exposed portion 321a and the second exposed portion 322a are electrically connected to each other. Thus, it is not necessary to separately provide a gas sensor that senses electrolyte vapor to detect the leakage like the related art. Only the sensing part 320 may extend from the body part 310 of the existing flexible printed circuit board 300 and the sensing part 320 may be provided with the first exposed portion 321a and the second exposed portion 322a to sense whether the electrolyte leaks, so that the safety of the battery is secured and also the space utilization in the module is increased, and the dead space is minimized to maximize the energy density of the module.

Next, the busbar frame assembly 200 will be described in detail with reference to FIGS. 3 to 5. The busbar frame assembly 200 may include a busbar 210, the fixing plate 220, and a cover plate 230.

First, the busbar 210 is made of a metal and may be electrically coupled to an electrode lead of the pouch assembly. In detail, the electrode lead may be inserted into a lead insertion part 221 of the fixing plate 220 to be described later and then, coupled to the busbar 210, which is seated on a busbar seating part 222 in advance in a bending state, by welding. In addition, the busbar 210 may be connected to each of both sides of the flexible printed circuit board 300 and accordingly, the flexible printed circuit board 300 may read the cell voltage transmitted from the electrode lead.

The fixing plate 220 may include a fixing plate 220, which is a kind of an injection-molded product and in which a lead insertion part 221 having a slit having a shape passing through front and rear surfaces so that the electrode lead is inserted thereinto, a busbar seating part 222 provided at one side of the lead insertion part 221, and a terrace part 223 extending from a lower portion of the lead insertion part 221 to a side of the pouch cell assembly 100, are provided. Here, the first exposed portion 321a and the second exposed portion 322a, which are described above, may be disposed on a top surface of the terrace part 223. In general, when the electrolyte leaks from the pouch cell, a case frequently occurs, in which the electrolyte flows around the busbar frame assembly 200 disposed at each of the both sides of the pouch assembly or the fixing plate 220 of the busbar frame assembly 200. Thus, when the first exposed portion 321a and the second exposed portion 322a for detecting the electrolyte are disposed on the top surface of the terrace part 223 of the fixing plate 220, it may be more effectively detected whether the electrolyte leaks in the module, in a state in which the first exposed portion 321a and the second exposed portion 322a, each of which has flexibility, are stably disposed.

The cover plate 230 may cover the busbar 210 seated on the busbar seating part 222 of the fixing plate 220 and be coupled to the fixing plate 220. Accordingly, the busbar 210 may be protected from an external impact or being damaged.

In addition, as illustrated in FIG. 3, the secondary battery module 10 according to the present disclosure may further include a module case 400, which has both ends opened and in which the pouch cell assembly 100 and the busbar frame assembly 200 are accommodated, and an end plate 500 which covers each of both the opened ends of the module case 400.

The module case 400 (or mono-frame) may serve as an enclosure that maintains a shape of the secondary battery module 10 and protects the pouch cell assembly 100, the flexible printed circuit board 300, and the busbar frame assembly 200 that are accommodated therein. The module case 400 may have a shape in which the both ends are opened, and the pouch cell assembly 100 may be inserted through the both ends.

In addition, the secondary battery module 10 according to the present disclosure may further include a connector 600 that transmits a signal output from the flexible printed circuit board 300 to an external battery management system (BMS). Here, the signal output from the flexible printed circuit board 300 may be a signal obtained by sensing the cell voltage transmitted from the busbar 210, the temperature inside the module, or whether the electrolyte leaks as described above. In particular, in the secondary battery module 10 according to the present disclosure, the sensing part 320 may sense whether the first exposed portion 321a and the second exposed portion 322a are electrically connected to each other by the moisture or electrolyte, and the connector 600 may transmit the result of the sensing to a micro controller unit (MCU) of the BMS to detect whether the electrolyte leaks.

### Embodiment 2

Embodiment 2 of the present disclosure is different from Embodiment 1 in that the terrace part 223 of the fixing plate 220 according to Embodiment 1 includes a first inclined part 223a and a second inclined part 223b. Thus, the other components of the secondary battery module 10 may be understood as the same as those described in Embodiment 1 and illustrated in FIGS. 3 to 6b, and also resultant effects may be expected to be the same.

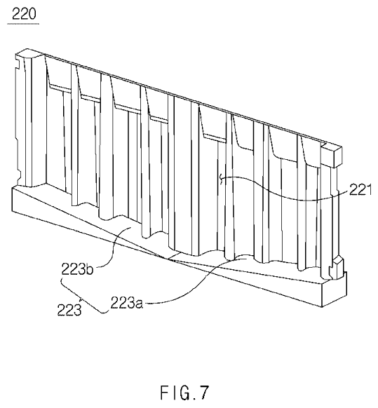

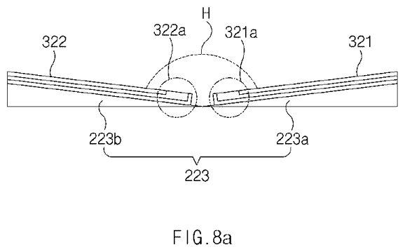

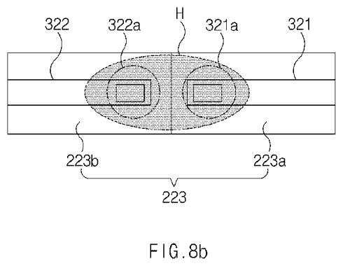

FIG. 7 is a perspective view illustrating a fixing plate of a secondary battery module according to Embodiment 2 of the present disclosure. FIG. 8a is a side view illustrating a first extension line part, a second extension line part, and a terrace part of the secondary battery module according to Embodiment 2 of the present disclosure when viewed from a side. FIG. 8b is a plan view illustrating the first extension line part, the second extension line part, and the terrace part of the secondary battery module according to Embodiment 2 of the present disclosure when viewed from above.

Referring to FIG. 7, a terrace part 223 of a fixing plate 220 according to Embodiment 2 of the present disclosure includes the first inclined part 223a having a height that gradually decreases from one side to a center, and the second inclined part 223b having a height that gradually decreases from the other side to the center. In addition, as illustrated in FIGS. 8a and 8b, a first exposed portion 321a is disposed on a top surface of the first inclined part 223a, and a second exposed portion 322a is disposed on a top surface of the second inclined part 223b.

Here, each of the first inclined part 223a and the second inclined part 223b may be a flat surface but is not necessarily limited thereto. Each of the first inclined part 223a and the second inclined part 223b may be provided as a curved surface. For example, each of the first inclined part 223a and the second inclined part 223b may have various shapes as long as the first inclined part 223a is provided to have the height that gradually decreases from the one side to the center of the terrace part 223 and the second inclined part 223b is provided to have the height that gradually decreases from the other side to the center thereof as described above, so that the first inclined part 223a and the second inclined part 223b are connected to each other in a state of being in contact with each other, and the terrace part 223 has a central portion that is recessed when viewed from a side.

As the secondary battery module 10 according to Embodiment 2 of the present disclosure includes the first inclined part 223a and the second inclined part 223b as above, even when a small amount of the electrolyte leaks, the electrolyte is collected between the first inclined part 223a and the second inclined part 223b of the terrace part 223, each of which is provided to be concave as the height gradually decreases toward the center. The electrolyte may be detected from the first exposed portion 321a and the second exposed portion 322a and thus, leakage or submergence detectability may be improved.

### Embodiment 3

Embodiment 3 of the present disclosure is different from Embodiments 1 and 2 in that Embodiment 3 is a flexible printed circuit board 300 included in the secondary battery module 10 according to each of Embodiments 1 and 2. Thus, the detailed configuration and effects of the flexible printed circuit board 300 described below may be understood as the same as those described in Embodiments 1 and 2 and illustrated in FIGS. 3 to 8b.

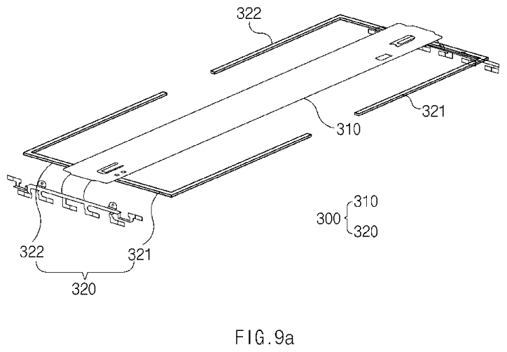

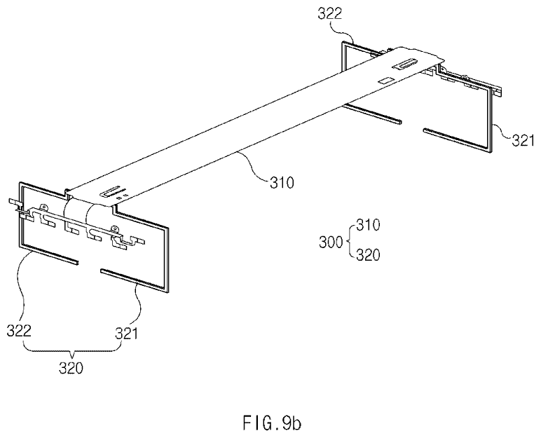

FIG. 9a is a perspective view illustrating the flexible printed circuit board 300 according to Embodiment 3 of the present disclosure. FIG. 9b is a perspective view illustrating a state in which a first extension line part and a second extension line part are bent in the flexible printed circuit board 300 according to Embodiment 3 of the present disclosure.

Referring to FIGS. 9a and 9b, the flexible printed circuit board 300 according to Embodiment 3 of the present disclosure is the flexible printed circuit board (FPCB) 300 in which a film layer is stacked on at least one surface of a metal layer. The flexible printed circuit board 300 includes a body part 310 and a sensing part 320 that extends from the body part 310 and is provided at each of one side and the other side in a width direction of the body part 310 to sense leakage of moisture or an electrolyte, at least one of one side or the other side in a longitudinal direction of the body part 310. In addition, the sensing part 320 may include a first

extension line part 321, which extends toward one side in the width direction of the body part 310, and a second extension line part 322 which extends toward the other side in the width direction of body part 310.

In the flexible printed circuit board 300 according to Embodiment 3 of the present disclosure, the first extension line part 321 extends toward the one side in the width direction of the body part 310 and may have an area of at least a portion including an end, which is provided to be parallel to the longitudinal direction of the body part 310, and the second extension line part 322 extends toward the other side in the width direction of body part 310 and may have an area of at least a portion including an end, which is provided to be parallel to the longitudinal direction of the body part 310.

As above, each of the first extension line part 321 and the second extension line part 322 may extend integrally from the body part 310 of the flexible printed circuit board 300. For example, the body part 310 and each of the first extension line part 321 and the second extension line part 322 may be provided by cutting the sheet-shaped flexible printed circuit board 300. Thus, when the cutting is performed so that the first extension line part 321 is provided to have the area of at least a portion including the end, which is parallel to the longitudinal direction of the body part 310, and the second extension line part 322 is provided to have the area of at least a portion including the end, which is parallel to the longitudinal direction of the body part 310, the cutting area of the sheet-shaped flexible printed circuit board 300 may be minimized. Accordingly, yield of products may be maximized to reduce the costs.

Each of the first extension line part 321 and the second extension line part 322 may be provided to be bendable. As each of the first extension line part 321 and the second extension line part 322 is provided to be bendable as above, the total volume occupied by the sensing part 320 of the flexible printed circuit board 300 during the bending may be minimized, and the sensing part 320 may be mounted in devices or frames having various shapes with an occupied space minimized. In particular, the sensing part 320 may be mounted in the module as described in Embodiment 1 to maximize the energy density.

In addition, the first extension line part 321 may have an end having a first exposed portion 321a at which the metal layer is exposed, and the second extension line part 322 may have an end having a second exposed portion 322a at which the metal layer is exposed.

Here, the respective ends of the first extension line part 321 and the second extension line part 322 may be bent to face each other in a state of being spaced a predetermined gap from each other. In more detail, as the first extension line part 321 and the second extension line part 322 are bent, the first exposed portion 321a and the second exposed portion 322a may be bent to face each other in a state of being spaced a predetermined gap from each other.

The sensing part 320 according to Embodiment 3 of the present disclosure may sense whether the first exposed portion 321a and the second exposed portion 322a are electrically connected to each other by moisture or electrolyte. That is, when the first exposed portion 321a and the second exposed portion 322a are submerged together by the moisture or electrolyte, the first exposed portion 321a and the second exposed portion 322a may be electrically connected to each other and accordingly, the electrolyte leakage or submergence may be sensed.

Although the present disclosure has been described with reference to the limited embodiments and drawings, the present disclosure is not limited thereto and may be variously implemented by those of ordinary skill in the art to which the present disclosure pertains, within the technical idea of the present disclosure and an equivalent of the appended claims.

### DESCRIPTION OF THE SYMBOLS

10: Secondary battery module

100: Pouch cell assembly

200: Busbar frame assembly

210: Busbar

220: Fixing plate

221: Lead insertion part

222: Busbar seating part

223: Terrace part

223a: First inclined part

223b: Second inclined part

230: Cover plate

300: Flexible printed circuit board

310: Body part

320: Sensing part

321: First extension line part

321a: First exposed portion

322: Second extension line part

322a: Second exposed portion

400: Module case

500: End plate

600: Connector

H: Electrolyte or moisture

1. A secondary battery module, comprising:
a pouch cell assembly comprising a plurality of pouch cells arranged in a thickness direction;
a pair of busbar frame assemblies coupled to each of a first side and a second side of the pouch cell assembly; and
a flexible printed circuit board (FPCB) coupled to each of the busbar frame assemblies and having a metal layer and a film layer on at least one surface of the metal layer,
wherein the flexible printed circuit board comprises:
a body part provided between the pair of busbar frame assemblies coupled to the first side and the second side of the pouch cell assembly, respectively; and
a sensing part extending from the body part, wherein the sensing part extends from one side or both sides in a longitudinal direction of the body part which is parallel to the thickness direction of the pouch cell assembly, and provided at both sides in a width direction of the body part to sense leakage of moisture or an electrolyte.

2. The secondary battery module of claim 1, wherein the sensing part further comprises:
a first extension line part extending toward one side in the width direction of the body part; and
a second extension line part extending toward the other side in the width direction of the body part.

3. The secondary battery module of claim 2, wherein each of the first extension line part and the second extension line part is bent along a circumference of each of the busbar frame assemblies.

4. The secondary battery module of claim 3, wherein each of the first extension line part and the second extension line part has an end, respectively, and the ends of the first extension line part and the second extension line part are bent to face each other in a state of being spaced apart by a predetermined gap from each other.

5. The secondary battery module of claim 3, wherein:
the first extension line part has a first end having a first exposed portion at which the metal layer is exposed, and
the second extension line part has a second end having a second exposed portion at which the metal layer is exposed.

6. The secondary battery module of claim 5, wherein the sensing part senses whether the first exposed portion and the second exposed portion are electrically connected to each other by moisture or electrolyte.

7. The secondary battery module of claim 5, wherein each of the busbar frame assemblies comprises:
a busbar electrically coupled to an electrode lead of the pouch cell assembly; and
a fixing plate comprising a lead insertion part having a slit allowing the electrode lead to pass through front and rear surfaces of the fixing plate so that the electrode lead is inserted thereinto, a busbar seating part provided at one side of the lead insertion part, and a terrace part extending from a lower portion of the lead insertion part to a side of the pouch cell assembly,
wherein the first exposed portion and the second exposed portion are disposed on a top surface of the terrace part.

8. The secondary battery module of claim 7, wherein each of the busbar frame assemblies further comprises a cover plate covering the busbar and coupled to the fixing plate.

9. The secondary battery module of claim 1, further comprising:
a housing which has both ends opened and in which the pouch cell assembly and the pair of busbar frame assemblies are accommodated; and
an end plate covering each of the opened ends of the housing.

10. The secondary battery module of claim 1, further comprising:
a connector transmitting a signal output from the flexible printed circuit board to an external battery management system (BMS).

11. The secondary battery module of claim 7, wherein the terrace part comprises:
a first inclined part having a height that gradually decreases from one side of the terrace part to a center; and
a second inclined part having a height that gradually decreases from the other side of the terrace part to the center,
wherein the first exposed portion is disposed on a top surface of the first inclined part, and the second exposed portion is disposed on a top surface of the second inclined part.

12. A flexible printed circuit board (FPCB) in which a film layer is stacked on at least one surface of a metal layer, the flexible printed circuit board comprising:
a body part; and
a sensing part extending from the body part and provided at both sides in a width direction of the body part to sense leakage of moisture or an electrolyte, wherein the sensing part extends from one side or both sides in a longitudinal direction of the body part.

13. The flexible printed circuit board of claim 12, wherein the sensing part further comprises:
a first extension line part extending toward one side in the width direction of the body part; and
a second extension line part extending toward the other side in the width direction of the body part.

14. The flexible printed circuit board of claim 13, wherein;
the first extension line part extends toward the one side in the width direction of the body part and has an area of at least a portion comprising a first end, which is provided to be parallel to the longitudinal direction of the body part, and
the second extension line part extends toward the other side in the width direction of body part and has an area of at least a portion comprising a second end, which is provided to be parallel to the longitudinal direction of the body part.

15. The flexible printed circuit board of claim 13, wherein each of the first extension line part and the second extension line part is bendable.

16. The flexible printed circuit board of claim 13, wherein:
the first extension line part has the first end having a first exposed portion at which the metal layer is exposed, and
the second extension line part has the second end having a second exposed portion at which the metal layer is exposed.

17. The flexible printed circuit board of claim 16, wherein the sensing part senses whether the first exposed portion and the second exposed portion are electrically connected to each other by moisture or electrolyte.
